(19) United States
(12) Patent Application Publication
(10) Pub. No.: US 2023/0065165 A1
(43) Pub. Date: Mar. 2, 2023

(54) WRITE-ASSIST FOR SEQUENTIAL SRAM

(71) Applicant: Meta Platforms Technologies, LLC, Menlo Park, CA (US)

(72) Inventors: Edith DALLARD, San Mateo, CA (US); Huichu LIU, Santa Clara, CA (US); Daniel Henry MORRIS, Mountain View, CA (US); Doyun KIM, Seoul (KR)

(21) Appl. No.: 17/554,838

(22) Filed: Dec. 17, 2021

Related U.S. Application Data
(60) Provisional application No. 63/239,683, filed on Sep. 1, 2021.

(51) Int. Cl. G11C 11/419; G11C 11/418

(52) U.S. Cl. CPC G11C 11/419; G11C 11/418

(57) ABSTRACT

In some embodiments, an apparatus comprises: a static random access memory (SRAM) device. The SRAM device may have a bit cell array comprising a plurality of bit cells, the plurality of bit cells arranged in a plurality of rows and a plurality of columns, each column of the plurality of columns operatively coupled to a pair of bit lines. The apparatus may comprise a controller configured to: assert a word line associated with a row; perform a sequence of write operations while the word line remains asserted, each write operation corresponding to a bit cell associated with a different column of the plurality of columns and the row, wherein the word line has an elevated voltage relative to a non-elevated voltage during at least a portion of the sequence of write operations; and de-assert the word line after the sequence of write operations are performed.

### CROSS-REFERENCE TO RELATED APPLICATIONS

This application claims priority under 35 U.S.C. § 119 to U.S. Provisional Application No. 63/239,683, filed on Sep. 1, 2021 the contents of which are hereby incorporated by reference in their entirety for all purposes.

### BACKGROUND

Writing to a bit cell of an SRAM device is performed by activating a word line to select a particular row of the bit cell array, and then using write drivers to sink current through the bit cell pass transistors. The gate of the pass transistors is connected to the word line, which, when activated, typically has the word line supply voltage (i.e., the SRAM supply voltage). The current that passes in and out of the pass transistors used to drive a bit cell during a write operation may be too small, which may lead to a high likelihood of a write operation failure.

Accordingly, methods, systems, and techniques for improving the fidelity of write operations are desirable.

### SUMMARY

This disclosure relates generally to wrist-assist for sequential static random access memory (SRAM) devices. According to certain embodiments, an apparatus may comprise: an SRAM device comprising: a bit cell array comprising a plurality of bit cells, the plurality of bit cells arranged in a plurality of rows and a plurality of columns, each column of the plurality of columns operatively coupled to a pair of bit lines. In some embodiments, the apparatus may comprise a controller configured to: assert a word line associated with a row of the plurality of rows; perform a sequence of write operations while the word line remains asserted, each write operation of the sequence of write operations corresponding to a bit cell associated with a different column of the plurality of columns and the row, wherein the word line has an elevated voltage relative to a non-elevated voltage during at least a portion of the sequence of write operations; and de-assert the word line after the sequence of write operations are performed.

In some examples, the non-elevated voltage corresponds to a supply voltage associated with addressing circuitry of the SRAM device.

In some examples, the non-elevated voltage is associated with a supply voltage of a word line driver of the word line, and wherein the non-elevated voltage is used to assert the word line.

In some examples, to perform the sequence of write operations, the controller is configured to cause the word line to have the elevated voltage for an entire duration of each of the sequence of write operations.

In some examples, to perform the sequence of write operations, the controller is configured to cause the word line to have the supply voltage during a first portion of each write operation of the sequence of write operations, and to have the elevated voltage during a second portion of each write operation of the sequence of write operations.

In some examples, the elevated voltage is determined based at least in part on conditions comprising process variations, voltage conditions, or temperature conditions.

In some examples, the controller is configured to cause the word line to have the non-elevated voltage or the elevated voltage by controlling a voltage of a word line driver that is operatively coupled to the word line. In some examples, the controller is configured to cause the word line to have the non-elevated voltage by causing the word line driver to be powered by a word line supply, and wherein the controller is configured to cause the word line to have the elevated voltage by causing the word line driver to be floating and capacitively coupled to one or more boost buffers. In some examples, the capacitive coupling comprises one or more boost capacitors, the one or more boost capacitors comprising one or more metal-oxide-silicon capacitors (MOSCAPs) or one or more metal-insulator-metal capacitors (MIMCAPs). In some examples, the controller is configured to select boost capacitors of a set of available boost capacitors to be used to capacitively couple the word line driver to the one or more boost buffers during operation of the SRAM device, and wherein a magnitude of the second voltage is dependent on a number of boost capacitors selected. In some examples, the boost capacitors of the set of available boost capacitors are selected based at least in part on conditions comprising process variations, voltage conditions, or temperature conditions. In some examples, the boost capacitors of the set of available boost capacitors are selected by accessing a look up table during operation of the SRAM device. In some examples, the one or more boost capacitors comprises at least two boost capacitors, each controlled by a switching signal, and wherein a timing of a first switching signal associated with a first boost capacitor differs from a timing of a second switching signal associated with a second boost capacitor.

In some examples, the controller is configured to cause the word line to have the word line voltage or the elevated voltage by controlling a voltage of the word line while causing a word line driver operatively coupled to the word line to have the word line voltage. In some examples, the controller is configured to cause the word line to have the elevated voltage by transferring charge from one or more boost buffers to the word line, wherein the one or more boost buffers are capacitively coupled to the word line by one or more boost capacitors, and wherein the one or more boost capacitors are implemented as metal routes parallel to the word line. In some examples, to transfer charge from the one or more boost buffers to the word line, the controller is configured to cause the word line driver to be in a high impedance mode. In some examples, the metal routes and the word line are implemented in an M3 layer of an integrated circuit on which the SRAM device is fabricated.

According to some embodiments, a method comprises: asserting a word line associated with a row of a plurality of rows of a static random access memory (SRAM) device, the SRAM device comprising a bit cell array comprising a plurality of bit cells, the plurality of bit cells arranged in a plurality of rows and a plurality of columns, each column of the plurality of columns operatively coupled to a pair of bit lines; performing a sequence of write operations while the word line remains asserted, each write operation of the sequence of write operations corresponding to a bit cell associated with a different column of the plurality of columns and the row, wherein the word line has an elevated voltage relative to a non-elevated voltage during at least a portion of the sequence of write operations; and de-asserting the word line after the sequence of write operations are performed.

In some examples, performing the sequence of write operations comprises causing the word line to have the elevated voltage for an entire duration of each of the sequence of write operations.

In some examples, performing the sequence of write operations comprises causing the word line to have the supply voltage during a first portion of each write operation of the sequence of write operations, and to have the elevated voltage during a second portion of each write operation of the sequence of write operations.

In some examples, the method further comprises causing the word line to have the non-elevated voltage or the elevated voltage by controlling a voltage of a word line driver that is operatively coupled to the word line. In some examples, causing the word line to have the non-elevated voltage comprises causing the word line driver to be powered by a word line supply, and wherein causing the word line to have the elevated voltage comprises causing the word line driver to be floating and capacitively coupled to one or more boost buffers.

In some examples, the method further comprises causing the word line to have the word line voltage or the elevated voltage by controlling a voltage of the word line while causing a word line driver operatively coupled to the word line to have the word line voltage. In some examples, causing the word line to have the elevated voltage comprises transferring charge from one or more boost buffers to the word line, wherein the one or more boost buffers are capacitively coupled to the word line by one or more boost capacitors, and wherein the one or more boost capacitors are implemented as metal routes parallel to the word line.

According to some embodiments, an apparatus comprises: an SRAM device comprising a bit cell array comprising a plurality of bit cells, the plurality of bit cells arranged in a plurality of rows and a plurality of columns, each column of the plurality of columns operatively coupled to a pair of bit lines. In some embodiments, the apparatus comprises: means for asserting a word line associated with a row of the plurality of rows; means for performing a sequence of write operations while the word line remains asserted, each write operation of the sequence of write operations corresponding to a bit cell associated with a different column of the plurality of columns and the row, wherein the word line has an elevated voltage relative to a non-elevated voltage during at least a portion of the sequence of write operations; and means for de-asserting the word line after the sequence of write operations are performed.

### BRIEF DESCRIPTION OF THE DRAWINGS

Illustrative embodiments are described in detail below with reference to the following figures.

FIG. 1A is a schematic diagram that shows an example implementation of a static random access memory (SRAM) device in accordance with some embodiments.

FIG. 1B is an example timing diagram that illustrates sequential memory operations using a sequential SRAM device in accordance with some embodiments.

FIG. 2 is a schematic diagram of pass transistors of an SRAM device during a write operation in accordance with some embodiments.

FIG. 3 is an example timing diagram that illustrates a voltage boost that is maintained during a sequence of write operations in accordance with some embodiments.

FIG. 4 is an example timing diagram that illustrates a voltage boost that is applied for each write operation of a sequence of write operations in accordance with some embodiments.

FIG. 5 is an example schematic diagram of circuitry for boosting a voltage of a word line driver in accordance with some embodiments.

FIG. 6 is a flowchart of an example process for providing a voltage boost that is maintained during a sequence of write operations in accordance with some embodiments.

FIG. 7 is a flowchart of an example process for providing a voltage boost that is applied for each write operation of a sequence of write operations in accordance with some embodiments.

FIGS. 8A and 8B illustrate example configurations of boost capacitors for boosting a voltage of a word line driver in accordance with some embodiments.

FIGS. 9A and 9B illustrate example diagrams for boosting a voltage of a word line signal in accordance with some embodiments.

FIG. 10 is an example schematic diagram for determining a number of boost capacitors in accordance with some embodiments.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

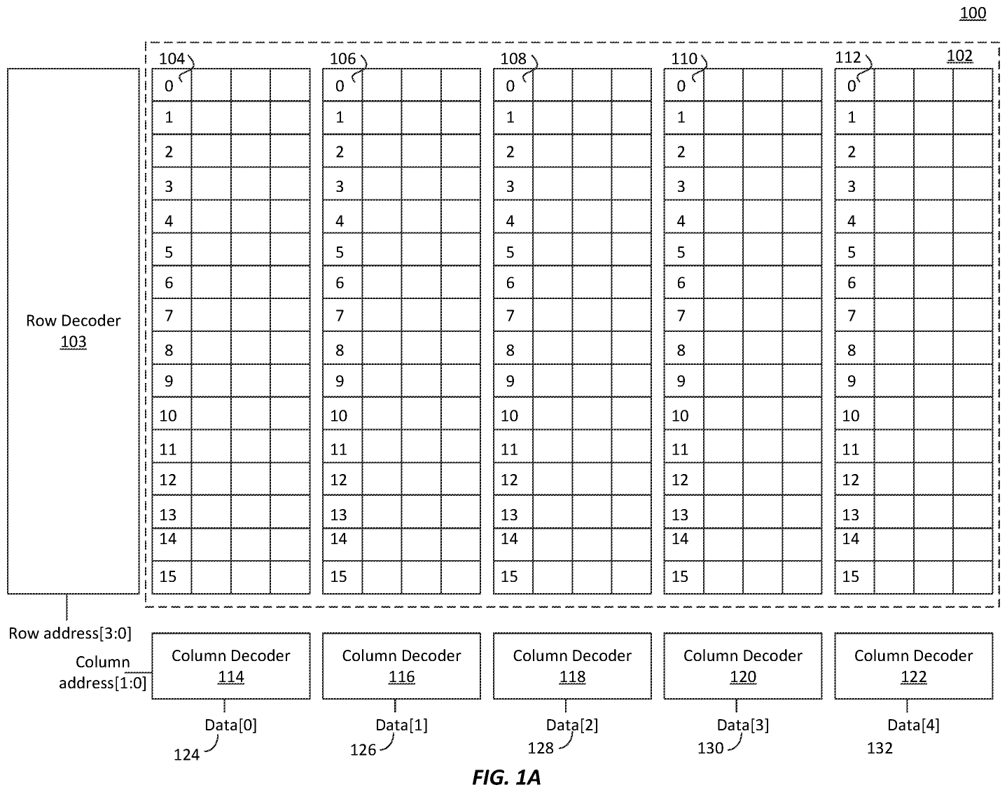

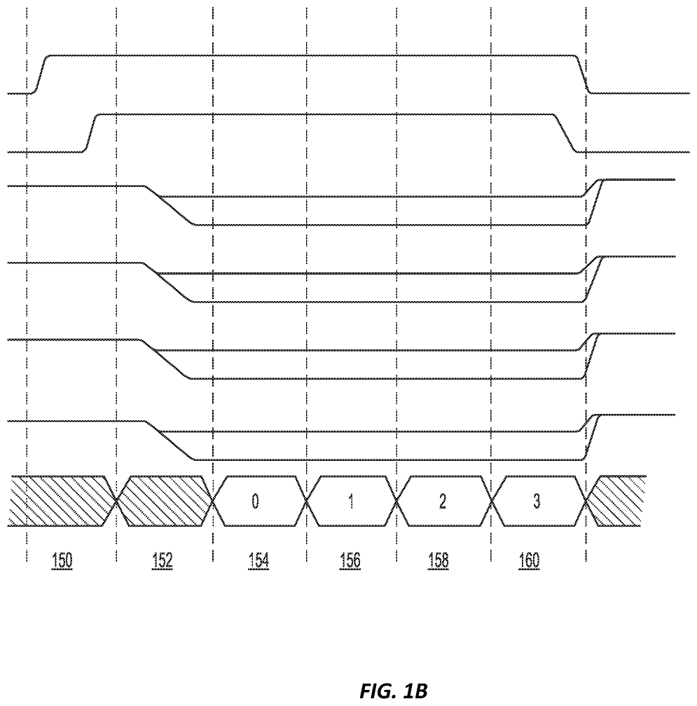

To perform a write operation on a bit cell of an SRAM device, a pair of bit lines (i.e., lbl and lblb) are pre-charged. Then, the bit lines are set to the value to be written, and a word line associated with the bit cell is asserted to select the row associated with the bit cell. It should be noted that the word line may be asserted and the bit lines are set to the value to be written in any suitable order relative to each other. When the word line is asserted, the word line has a voltage corresponding to the word line supply voltage (generally referred to herein as “VDDA”), typically associated with the SRAM device supply voltage. Write drivers are used to sink current through a pair of bit cell pass transistors corresponding to the bit cell. The gate of each bit cell pass transistor is operatively connected to the word line, and therefore has the word line voltage. The drain current, which passes in and out of the pass transistors, is used to drive the bit cell during the write operation. The magnitude of the drain current depends on the magnitude of the gate voltage. In some cases, the magnitude of the drain current may be too small, which may lead to a write operation failure. While it may be possible to boost the gate voltage (and thereby boost the drain current) by increasing the overall supply voltage of the SRAM device, this would lead to an increase in power of the device. Moreover, this would boost the gate voltage even in conditions where such a boost is not necessary (e.g., at times when write operations are not being performed, at particular temperature conditions under which no gate voltage boost is necessary, etc.). Accordingly, a more targeted boosting of the word line voltage is desirable. Moreover, the techniques described herein are particularly suited to a sequential SRAM device operation, because the techniques described herein amortize the boosting of the word line voltage over multiple cycles of write operations. Sequential SRAM devices are described in more detail below in connection with FIGS. 1A and 1B.

It should be noted that, as used herein, when two elements, A and B, are described as being “operatively coupled,” A and B may be directly connected (e.g., without any intervening elements), or may be connected with one or more intervening elements (e.g., an element C connected to A and B). Additionally, it should be noted that, as used herein, when two elements A and B are described as being “connected,” A and B may be directly connected, or, in some implementations, may be connected with one or more intervening elements. As used herein, “operatively coupled” and “connected” may be used interchangeably, whereas “directly connected” may refer to an element A being connected to an element B with no intervening elements in between.

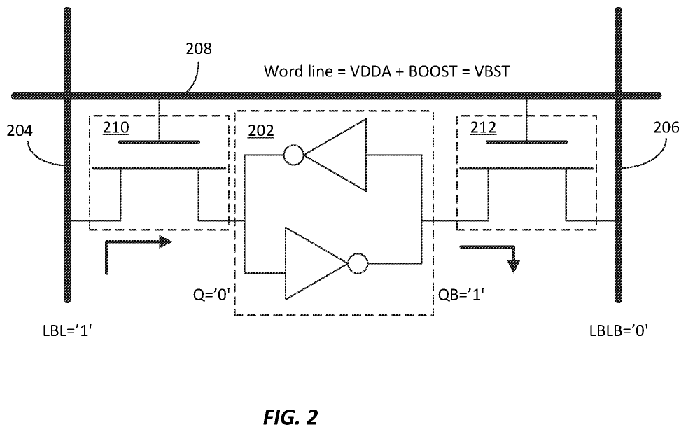

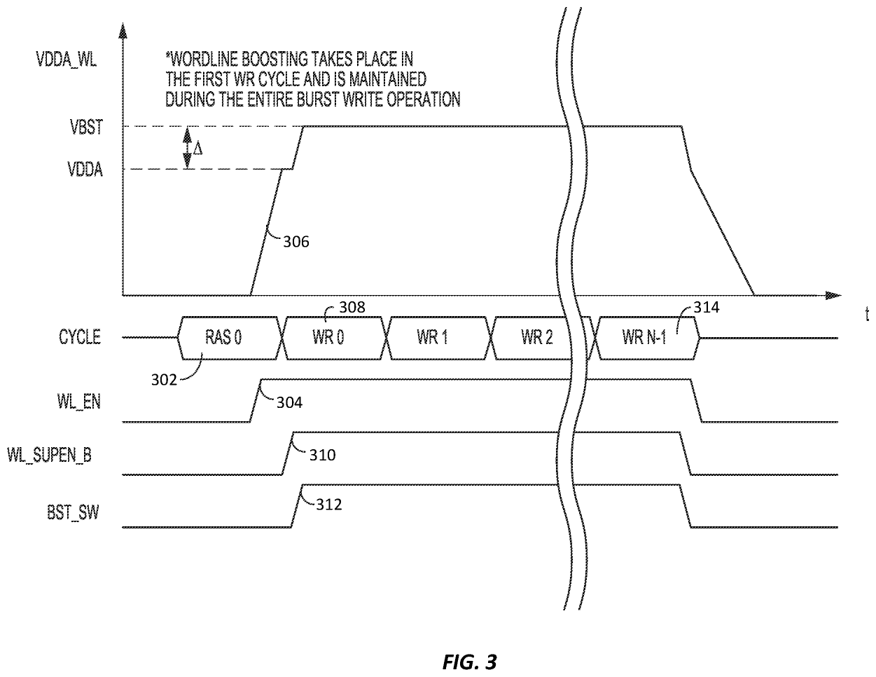

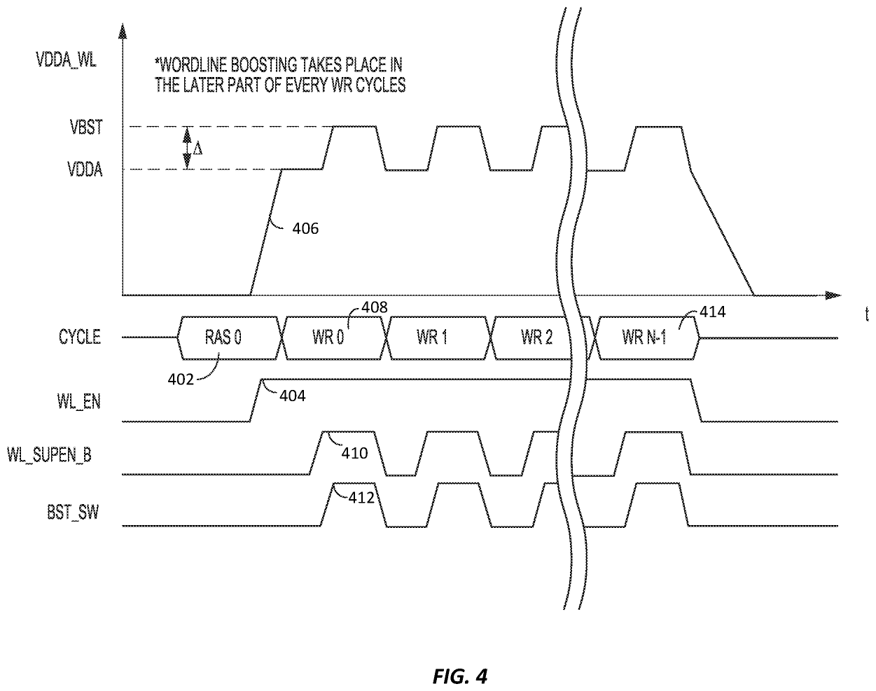

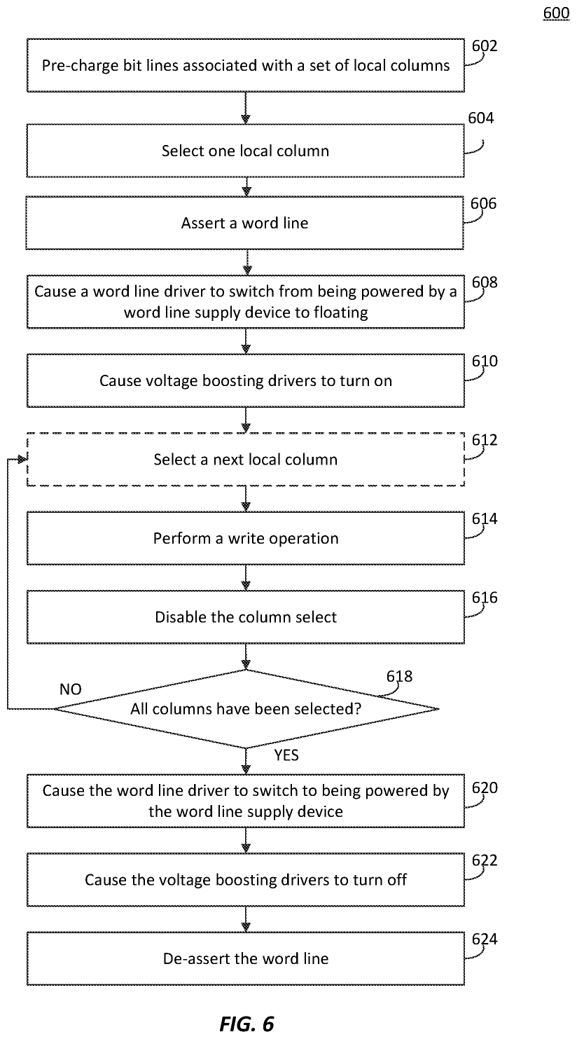

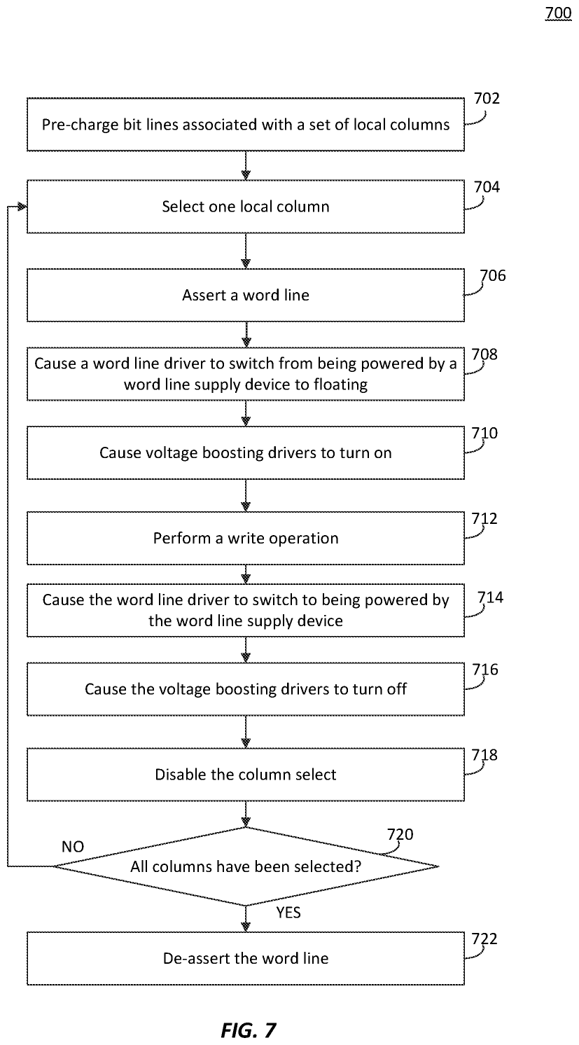

Disclosed herein are systems, methods, and techniques for boosting a word line voltage during at least a portion of a sequence of write operations, as shown in and described below in connection with FIG. 2. In some embodiments, the word line voltage is first set to a first voltage associated with a word line supply device, and then, during at least a portion of a sequence of write operations, boosted above the first voltage to a second voltage. In some embodiments, the second voltage is held for an entire sequence of write operations of a sequential SRAM device, as shown in and described below in connection with FIGS. 3 and 6. In some embodiments, the word line voltage returns to the first voltage associated with the word line supply device prior to each write operation in a sequence of write operations, and then is boosted to the second voltage during each write operation in the sequence of write operations, as shown in and described below in connection with FIGS. 4 and 7. By holding the word line voltage during a sequence of write operations (as is done in performing sequential SRAM write operations) and then boosting the word line voltage for a portion of the sequence of write operations rather than performing boosting for each write operations individually, large voltage swings during successive write operations can be reduced, thereby resulting in power savings.

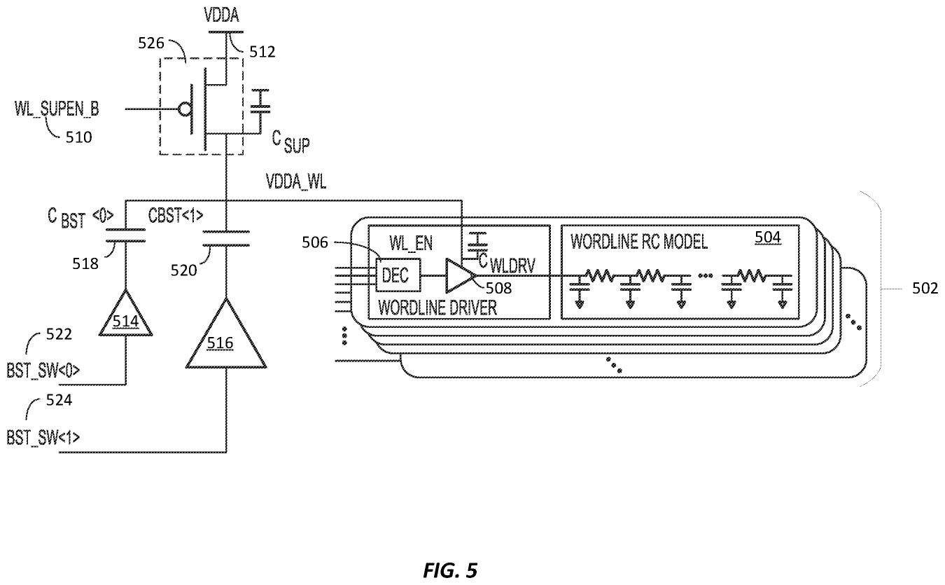

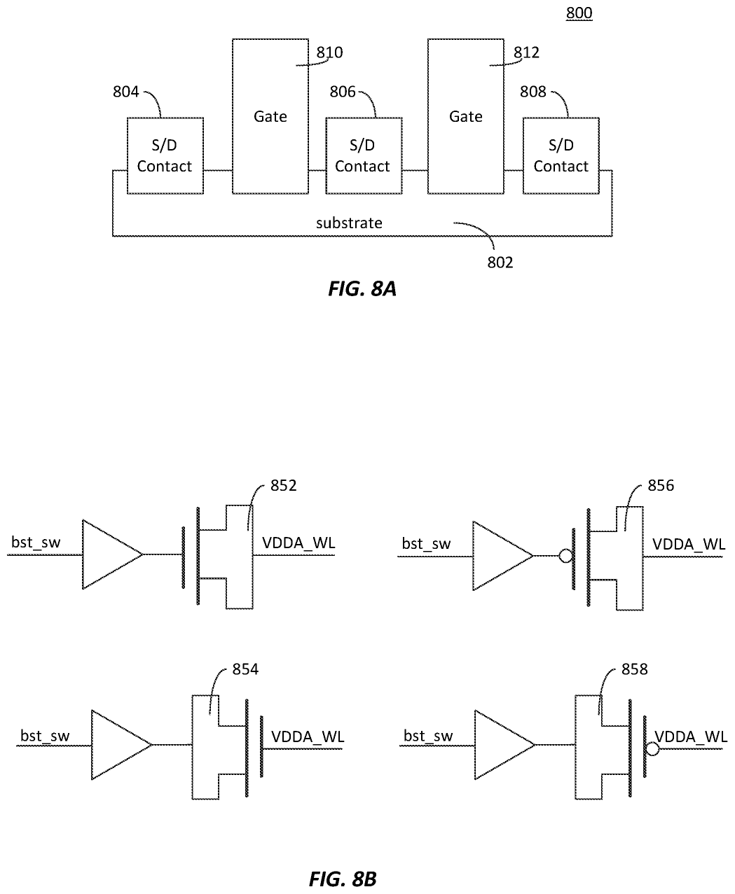

In some embodiments, the word line voltage is boosted by boosting a supply voltage of a word line driver, as shown in and described below in connection with FIG. 5. In some embodiments, the supply voltage of the word line driver is boosted by switching the word line driver from being driven by a word line supply device (providing a voltage of VDDA) to floating, where supply of the word line driver is then capacitively coupled to output of one or more boost buffers via one or more boost capacitors. In some embodiments, the boost capacitors may be metal-oxide-silicon capacitors (MOSCAPs) and/or metal-insulator-metal capacitors (MIMCAPs), as shown in and described below in connection with FIGS. 8A and 8B.

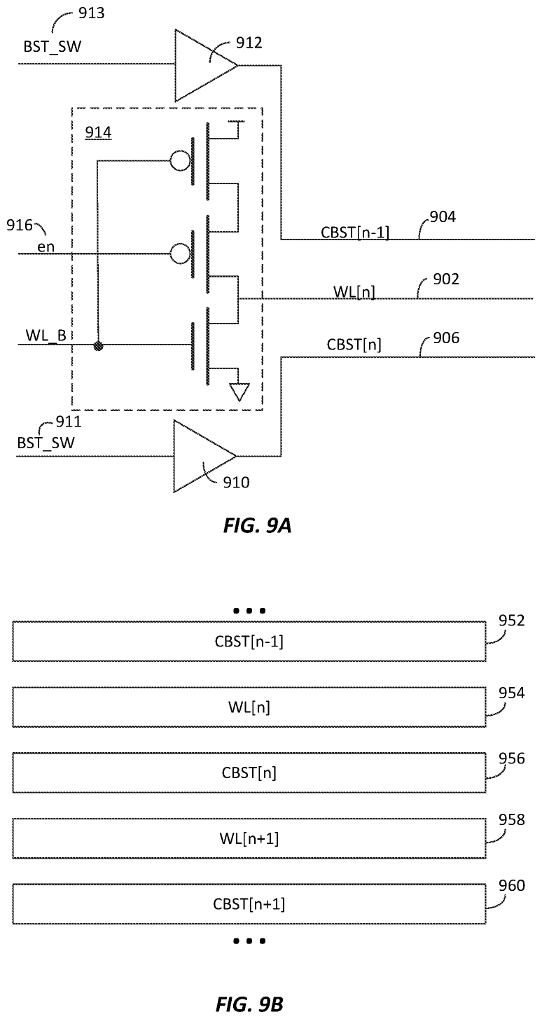

Alternatively, in some embodiments, the word line voltage is boosted by boosting the word line signal directly. In some such implementations, the word line signal is boosted directly by transferring charge from one or more boosting drivers (i.e., boost buffers) via capacitive coupling using one or more boost capacitors. In some embodiments, the boost capacitors may take a parallel route to the word line (e.g., on a layer of an integrated circuit on which the SRAM device is implemented), as shown in and described below in connection with FIGS. 9A, and 9B.

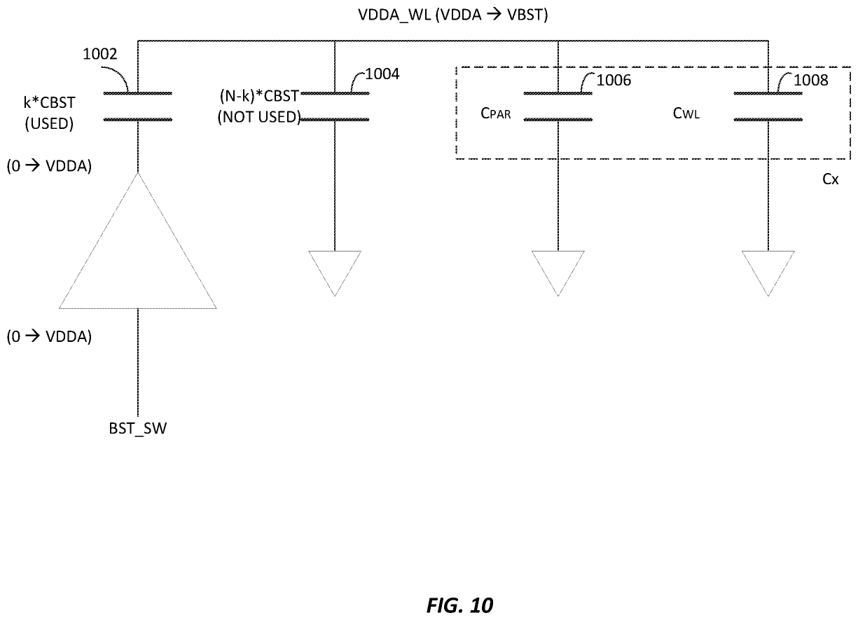

In some embodiments, an amount of boost voltage (i.e., the amount that a word line voltage is boosted above a word line supply voltage) is configurable. For example, the amount of boost voltage may be configured based on conditions that include process variations, voltage conditions, and/or temperature conditions (generally referred to herein as “PVT conditions”). In one example, the boost voltage may be greater during relatively sensitive conditions (e.g., low VDD conditions, higher temperature conditions, etc.) than for more robust conditions (e.g., higher VDD conditions, lower temperature conditions, etc.). In some embodiments, the boost voltage is configurable by varying a number of boost capacitors that capacitively couple a word line driver and/or a word line to boost buffers, as shown in and described below in connection with FIG. 10. For example, the voltage boost may be greater in instances in which more boost capacitors are used. In some embodiments, for a given set of PVT conditions, the number of boost capacitors may be identified using a look up table, for example, by using the PVT conditions as a key to the look up table to identify the corresponding boost capacitors to be used under the given PVT conditions. In some embodiments, the look up table may be configured during testing of the SRAM device (e.g., during factory testing), and the boost capacitors that are selected and/or used may then be configurable during operations of the SRAM device.

A static random access memory (SRAM) device includes a bit cell array arranged as a set of rows and a set of columns. The set of columns may be arranged as a set of column groups, where each column group includes a set of local columns. Each bit cell may be connected to a bit line pair (generally referred to herein as lbl and lblb). Each row may be connected to a word line. When accessing (whether as part of a read operation or as part of a write operation) a particular bit cell of the array, a row decoder is provided a row address, and the row decoder may be configured to activate (e.g., assert) the word line corresponding to the row address. During an operation, a column decoder associated with a particular column group may be configured to select, using a column multiplexer, a particular local column within the column group. The column multiplexer may select the pair of local bit lines, which are then connected to a data line pair in order to perform an operation. For example, in a read operation, a read/write circuit of the column multiplexer may sense the voltage on the bit line pair, which may then be transmitted to one or more interface circuits. As another example, in a write operation, the read/write circuit drives the pair of bit lines to store a data value in the corresponding bit cell.

FIG. 1A shows a schematic diagram of an implementation of an SRAM device 100 in accordance with some embodiments. As illustrated, SRAM device 100 has a bit cell array 102. Bit cell array 102 includes 16 rows. The rows of bit cell array 102 may be accessed by a row decoder 103. For example, row decoder 103 may take, as an input, a 4-bit row address that identifies a row of the 16 rows. Bit cell array 102 additionally includes five column groups, 104, 106, 108, 110, and 112. Each column group is associated with a column decoder. For example, column group 104 is associated with column decoder 114, column group 106 is associated with column decoder 116, column group 108 is associated with column decoder 118, column group 110 is associated with column decoder 120, and column group 112 is associated with column decoder 122. Each column group of bit cell array 102 includes four local columns. Each column decoder may include a column multiplexer (not shown) that selects a particular local column of the column group. The column multiplexer may operatively couple a bit line pair of the selected local column to a data line associated with the column decoder (e.g., one of data lines 124, 126, 128, 130, or 132). For bit cell array 102 of FIG. 1A, a column decoder may take, as an input, a 2 bit column address that identifies one of the four local columns.

With conventional SRAM devices, a word line corresponding to a particular row is asserted and de-asserted within a single clock cycle. In other words, when multiple bit cells associated with different columns and the same row are accessed sequentially, the word line is asserted and de-asserted for each access within the same row. Switching of the word line consumes power, which is problematic for devices requiring low power. Moreover, switching of the word line requires extra time due to switching transitions, thereby necessitating slower clock periods.

Sequential SRAM utilizes sequential accesses of bit cells within the same row to reduce power and to minimize switching transitions. With sequential SRAM, a word line associated with a particular row is asserted, and is held in an asserted state during accesses of multiple bit cells (e.g., corresponding to different local columns) of the row. Moreover, the bit lines associated with the multiple bit cells in different local columns are pre-charged at once for the multiple accesses.

FIG. 1B shows an example timing diagram for utilizing the SRAM device shown in FIG. 1A with sequential SRAM. As illustrated, during a first clock cycle 150, bit lines associated with local columns of a particular column group are pre-charged. Additionally, during first clock cycle 150, a word line associated with a particular row is asserted. During a second clock cycle 152, the bit lines of local columns develop a voltage difference. During the third, fourth, fifth, and sixth clock cycles (clock cycles 154-160, respectively), words (e.g., bit cells) are accessed from local columns 0-3, respectively. During access of each word, the word line remains asserted. The word line is de-asserted after the last bit cell of the column group has been accessed (e.g., after the last column of the column group has been selected).

Relative to conventional SRAM, sequential SRAM distributes memory accesses over more clock cycles. For example, in conventional SRAM, each clock cycle may be associated with a memory access, whereas, referring to the example shown in and described above in connection with FIG. 1B, four memory accesses occur over six clock cycles. In particular, two clock cycles are utilized for initialization prior to the memory accesses (e.g., asserting the word line and pre-charging the bit lines of the local columns to be selected). While the effective data accessed per cycle is lower with sequential SRAM than with conventional SRAM, because sequential SRAM operation does not require switching every clock cycle (e.g., to assert and de-assert the word line for every memory access), the overall device speed may be faster with sequential SRAM than conventional SRAM due to the reduced switching overhead.

FIG. 2 shows an example of a boost applied to a word line voltage in accordance with some embodiments. As illustrated, a cross-coupled inverters 202 are connected to a pair of bit lines 202 (lbl) and 204 (lblb). Cross-coupled inverters 202 are also connected to a pair of pass transistors 210 and 212. The gate of each pass transistor is operatively connected to a word line 208. To perform a write operation on cross-coupled inverters 202, a drain current passes in and out of pass transistors 210 and 212 to write a new value (which is written to bit lines 204 and 206) into cross-coupled inverters 202. Word line 208, when asserted, nominally has a voltage of VDDA, corresponding to the word line supply device. However, during at least a portion of the write operation, the voltage of word line 208 may be boosted by an amount denoted in FIG. 2 as “BOOST” to have a voltage of VBST. Because the gate of each pass transistor is connected to word line 208, boosting the voltage of word line 208 may thereby increase the drain current during the voltage boost, leading to a lower likelihood of a write operation failure.

As described below in connection with FIG. 3, the boosted voltage may be held for a sequence of write operations. Conversely, in some embodiments, the word line voltage may decrease to VDDA (i.e., the word line supply device voltage) at the end of the write operation and subsequently be boosted again to VBST during a subsequent write operation of a next bit cell, as shown in and described below in connection with FIG. 4. Regardless of whether the boosted voltage is held for the sequence of write operations or switched between VDDA and VBST (i.e., the boosted voltage) during the sequence of write operations, the techniques described herein take advantage of VDDA being a base line of the word line voltage during the sequence of write operations, as occurs during sequential SRAM operation. In other words, by boosting the word line voltage from VDDA to VBST rather from 0 to VBST during the sequence of write operations, overall power is reduced. It should be noted that the voltage boost may be provided by either boosting a supply voltage of a word line driver that provides the word line voltage (as shown in and described below in connection with FIG. 5), or by boosting the word line signal of the word line itself (as shown in and described below in connection with FIGS. 9A and 9B.

In some embodiments, a word line voltage may be held at a boosted voltage during a sequence of write operations. For example, in some embodiments, a row address strobe (RAS) cycle may begin for a sequence of write operations of a sequential SRAM device, where bit lines associated with a set of local columns that are associated with bit cells to be written to are pre-charged. Continuing with this example, a word line associated with a particular row address may be asserted, where, when the word line is asserted, the word line initially has a first voltage (i.e., VDDA) corresponding to a word line supply device. Continuing still further with this example, a first column of the set of columns may be selected, and a write operation may begin in connection with the first column. During the write operation, the voltage of the word line may be boosted above the first voltage to a second voltage (i.e., VBST). The voltage of the word line may then be held at the second, boosted voltage (i.e., VBST) during the remainder of the sequence of write operations corresponding to the other columns in the set of local columns. After the sequence of write operations has been completed, the voltage of the word line may be returned to the first voltage (i.e., VDDA), and subsequently, to 0.

FIG. 3 shows an example timing diagram for boosting a word line voltage over a series of write operations in accordance with some embodiments. As illustrated, during a RAS phase 302, a word line signal 304 is enabled, causing the corresponding word line to be asserted. Assertion of the word line causes a word line voltage 306 to rise to the first voltage, VDDA.

After RAS phase 302, a first write operation phase 308 occurs, for example, on a bit cell associated with a first local column of a set of local columns. During first write operation phase 308, word line voltage 306 rises to a second voltage, VBST. For example, word line voltage 306 may rise to VBST responsive to a voltage provided to the word line by a word line driver being increased, as shown in and described below in connection with FIG. 5. As a more particular example, word line voltage 306 may rise to VBST responsive to a word line driver switching from being connected to the word line supply device (providing the voltage of VDDA) to being floating, which may be instigated by switching of a word line supply enable signal 310. In the illustration of FIG. 3, word line supply enable signal 310 (denoted as “WL_SUPEN_B” is an inverted signal), accordingly, word line supply enable signal 310 having a high value causes the word line driver to no longer be connected to the word line supply device. Continuing with this example, when the word line driver is floating, the word line driver may be capacitively coupled to one or more boost drivers (e.g., boost buffers). The boost drivers may provide a higher output responsive to a boosting switch signal 312 (denoted as “BST_SW” in FIG. 3) taking a high value, thereby causing the output of the boost drivers to be transferred to the word line driver via the capacitive coupling. Alternatively, in some embodiments, word line voltage 306 may rise to VBST by causing charge to be transferred to the word line itself, as shown in and described below in connection with FIGS. 9A and 9B.

After the last write operation 314 in the sequence of write operations, word line voltage 306 drops from the second voltage (i.e., VBST) to the first voltage (i.e., VDDA), and then to 0. The drop to VDDA may occur by turning off the boost drivers (e.g., by switching boosting switch signal 312 to a low value) and by re-coupling the word line driver to the word line supply device (e.g., by switching word line supply enable signal 310 to a low value). The drop of the word line voltage to 0 may occur by de-asserting the word line (e.g., by switching word line signal 304 to a disabled state).

In some embodiments, there may be leakage associated with the word line voltage. Accordingly, in instances in which the word line is boosted throughout a sequence of write operations (as shown in and described above in connection with FIG. 3), there may be some leakage that causes the word line voltage to drift below the boosted voltage. The leakage may therefore cause the word line voltage to not effectively be boosted, thereby increasing a likelihood of write operation failures. To address this effect, in some embodiments, the word line voltage may be raised to a first voltage (i.e., VDDA) and boosted to the second voltage (i.e., VBST) for only a portion of each write operation in a sequence of write operations. In other words, during the sequence of write operations, the word line voltage may be boosted during a portion of a write operation and returned to the first voltage (VDDA) after a write operation. In contrast to the technique described above in connection with FIG. 3 in which the word line is held at the boosted voltage during the sequence of write operations without intermittently returning to the first voltage (VDDA), switching between VDDA and VBST may reduce leakage associated with the word line voltage, thereby reducing the likelihood of write operation failures.

FIG. 4 shows an example of a timing diagram for switching between a word line supply device voltage and a boosted voltage during a sequence of write operations in accordance with some embodiments. As illustrated, during a RAS phase 402, a word line is asserted (e.g., by switching a word line enable signal 404 to a high state). Assertion of the word line causes a word line voltage to rise to VDDA, i.e., the voltage associated with a word line supply device. During a first write operation phase 408 (e.g., associated with a bit cell of a first local column of a set of local columns on which the sequence of write operations is occurring), word line voltage 406 is VDDA during a first portion of first write operation phase 408, and rises to VBST during a second portion of first write operation phase 408.

In some embodiments, the rise in word line voltage 406 to VBST may occur due to switching a word line driver that powers the word line from a word line supply device to floating (e.g., by switching a word line supply enable signal 410, which is an inverted signal, from a low state to a high state) and by turning on one or more boost drivers (e.g., by switching a boosting switch 412 from a low state to a high state), as shown in and described below in connection with FIG. 5. Alternatively, in some embodiments, word line voltage 406 may rise to VBST by causing charge to be transferred to the word line itself, as shown in and described below in connection with FIGS. 9A and 9B.

After completion of first write operation phase 408, word line voltage 406 returns to VDDA. In some embodiments, this may occur by switching the word line driver back to being powered by the word line supply device (e.g., by switching word line supply enable signal 410 to a low state) and by turning off the one or more boost drivers (e.g., by switching boosting switch 412 to a low state). This process may then repeat for subsequent write operations. After a final write operation 414 in the sequence of write operations, the word line may be de-asserted, thereby causing word line voltage 406 to drop from VDDA to 0.

FIG. 5 shows an example of circuitry that can be used to boost a voltage of a word line driver in accordance with some embodiments. It should be noted that the circuitry of FIG. 5 may be used to boost the word line driver voltage during a sequence of write operations as shown in and described above in connection with FIG. 3, or to switch between the word line supply device voltage (i.e., VDDA) and the boosted voltage (i.e., VBST) during the sequence of write operations, as shown in and described above in connection with FIG. 4.

As illustrated in FIG. 5, a stack 502 of layers represents rows of a bit cell array, where each layer corresponds to a row of the bit cell array, and the corresponding word line drivers. Each word line across a bit cell array is represented by network 504, which includes a network of resistors and capacitors, where a pair of a resistor and a capacitor correspond to a portion of word line on top of corresponding bit cell. A decoder 506 is used to select a particular row, e.g., by asserting a particular word line. Also shown is a word line driver 508, which may include a buffer.

The voltage provided to word line driver 508 is mediated by a word line supply device enable signal 510. As shown in FIG. 5, in some embodiments, word line supply device enable signal 510 may be an inverted signal. Accordingly, when word line supply device enable signal 510 has a low value, word line driver 508 is connected to word line supply 512 through word line supply device 526 and therefore receives power from word line supply 512. Thus, when word line supply device enable signal 510 has a low value, the word line driver receives a supply voltage of VDDA.

Conversely, when word line supply device enable signal 510 has a high value, word line driver 508 is floating. In such instances, word line driver 508 may be capacitively coupled to one or more boost drivers. For example, as shown in FIG. 5, the word line driver is capacitively coupled to boost driver 514 via a boost capacitor 518 and is capacitively coupled to boost driver 516 via a boost capacitor 520. Each boost driver may be a buffer, where, when an input signal to the boost driver is in a high state, the output of the buffer is correspondingly high. Accordingly, when a value of a first boost switch 522 is high, charge of boost driver 514 is transferred to word line driver 508 via boost capacitor 518, and therefore boosts the voltage of word line driver 508. Similarly, when a value of a second boost switch 524 is high, charge of boost driver 516 is transferred to word line driver 508 via boost capacitor 520, and therefore boosts the voltage of word line driver 508.

It should be noted that FIG. 5 illustrates two boost drivers, and correspondingly, two boost capacitors. In some embodiments, any suitable number of boost drivers and/or boost capacitors can be used (e.g., 1, 2, 3, etc.). In some embodiments, boost capacitors of a set of available boost capacitors, that each capacitively couple the word line driver to a corresponding boost driver, can be selected to control a magnitude of the boost voltage. For example, the difference between VDDA and VBST may be proportional to a total capacitance of the boost capacitors. Accordingly, in some embodiments, by varying which available boost capacitors are selected using the corresponding boost switches, the magnitude of the boosted voltage (i.e., VBST) may be controlled. More detailed techniques for controlling a magnitude of the boosted voltage are shown in and described below in connection with FIG. 10.

FIG. 6 shows an example of a process 600 for boosting a voltage provided to a word line driver during a sequence of write operations in accordance with embodiments. In some implementations, execution of process 600 may allow the timing diagram shown in and described above in connection with FIG. 3 to be implemented using the circuitry shown in and described above in connection with FIG. 5. In some embodiments, blocks of process 600 may be implemented by a controller, such as a controller on a system on a chip (SOC) on which an SRAM device is included. In some embodiments, blocks of process 600 may be executed in an order other than what is shown in FIG. 6. In some embodiments, two or more blocks of process 600 may be executed substantially in parallel. In some embodiments, one or more blocks of process 600 may be omitted.

Process 600 can begin at block 602 by pre-charging bit lines associated with a set of local columns. Pre-charging the bit lines may serve to condition the bit lines prior to a sequence of write operations being performed. The set of local columns may be associated with a corresponding set of bit cells of a bit cell array at which the sequence of write operations are to be performed. It should be noted that pre-charging the bit lines may be considered part of a RAS cycle that is performed prior to the sequence of write operations. Prior to pre-charging the bit lines, process 600 may select all of the columns of the set of local columns, for example, using a column multiplexer.

At block 604, process 600 can select one local column of the set of local columns. For example, process 600 can select a first local column in the set of local columns, where a first write operation of the sequence of write operations is to be performed at a bit cell corresponding to the selected local column. The local column may be selected using a column multiplexer.

At block 606, process 600 may assert a word line corresponding to a particular row of the bit cell array. For example, process 600 may assert the word line by setting a word line enable signal to a high state or an enabled state, as shown in and described above in connection with FIGS. 3 and 5. In some embodiments, when the word line is asserted at block 606, the word line driver is connected to a word line supply 512, and therefore, the word line voltage is VDDA (e.g., the voltage provided by the word line supply device). In some embodiments, block 604 may occur responsive to a determination that pre-charging of the bit lines has finished.

At block 608, process 600 can cause the word line driver to switch from being powered by the word line supply device to floating. For example, in instances in which a word line supply enable signal is an inverted signal (e.g., as shown in and described above in connection with FIG. 5), process 600 can cause the word line supply enable signal to switch from a low state (in which the word line driver is connected to the word line supply 512) to a high state (in which the word line driver is not connected to the word line supply 512, and is therefore, in a floating state).

At block 610, process 600 can cause voltage boosting drivers to turn on. For example, process 600 can set one or more boost switches (e.g., as shown in and described above in connection with FIG. 5), each associated with a boost driver, to switch to a high state. Continuing with this example, when a boost switch is set to a high state, an output of a boost driver may be correspondingly high. The boost driver may be a buffer (and is generally referred to herein as a “boost buffer”). Accordingly, when a boost switch is set high, the charge stored in the buffer may be transferred to the word line driver via one or more boost capacitors that capacitively couple the word line driver to the boost driver. Accordingly, the voltage provided to the word line driver may be boosted (i.e., to VBST) by the charge transferred from the buffer.

In instances in which data has not yet been written to a bit cell associated with the local column selected at block 606, process 600 can skip block 612 and can perform the write operation at the bit cell at 614. Process 600 can then disable the column select at block 616. Process 600 can determine, at 618, whether all of the local columns in the set of columns have been selected. If, at 618, it is determined that not all of the local columns have been selected (“no” at block 618), process 600 can loop back to block 612 and can select the next local column of the set of local columns. Process 600 can then loop through blocks 612-618 until all of the columns in the set of local columns have been selected, and therefore, that all of the write operations in the sequence of write operations have been performed.

Conversely, if, at block 618, it is determined that all of the columns have been selected (“yes” at block 618), process 600 can proceed to block 620 and can cause the word line driver to switch back to being powered by the word line supply device. For example, in some embodiments, process 600 can switch a word line supply enable signal. As a more particular example, in instances in which the word line supply enable signal is an inverted signal, process 600 can switch the word line supply enable signal from a high state to a low state. In some embodiments, by operatively coupling the word line driver to the word line supply device, redundant charge is transferred back to VDDA to recycle the charge.

At block 622, process 600 causes the voltage boosting drivers to be turned off. For example, in some embodiments, process 600 can switch the boost switches to an off state or to a low state, thereby causing the output of the boost drivers to be correspondingly low. It should be noted that, after execution of blocks 618 and 620, the word line driver voltage drops from VBST to VDDA.

At block 624, process 600 de-asserts the word line.

FIG. 7 shows an example of a process 700 for switching a voltage provided to a word line driver between a word line supply device voltage (i.e., VDDA) and a boosted voltage (i.e., VBST) multiple times during a sequence of write operations in accordance with embodiments. In some implementations, execution of process 700 may allow the timing diagram shown in and described above in connection with FIG. 4 to be implemented using the circuitry shown in and described above in connection with FIG. 5 In some embodiments, blocks of process 700 may be implemented by a controller, such as a controller on a SOC on which an SRAM device is included. In some embodiments, blocks of process 700 may be executed in an order other than what is shown in FIG. 7. In some embodiments, two or more blocks of process 700 may be executed substantially in parallel. In some embodiments, one or more blocks of process 700 may be omitted.

Process 700 can begin at block 702 by pre-charging bit lines associated with a set of local columns. Pre-charging the bit lines may serve to condition the bit lines prior to write operations being performed. The set of local columns may be associated with a corresponding set of bit cells of a bit cell array at which the sequence of write operations are to be performed. It should be noted that pre-charging the bit lines may be considered part of a RAS cycle that is performed prior to the sequence of write operations. In some embodiments, prior to pre-charging the bit lines, process 700 may select all of the columns of the set of local columns, for example, using a column multiplexer.

At block 704, process 700 can select one local column of the set of local columns. For example, process 700 can select a first local column in the set of local columns, where a first write operation of the sequence of write operations is to be performed at a bit cell corresponding to the selected local column. The local column may be selected using a column multiplexer.

At block 706, process 700 may assert a word line corresponding to a particular row of the bit cell array. For example, process 700 may assert the word line by setting a word line enable signal to a high state or an enabled state, as shown in and described above in connection with FIGS. 4 and 5. In some embodiments, when the word line is asserted at block 706, the word line driver is connected to a word line supply, and therefore, the word line voltage is VDDA (e.g., the voltage provided by the word line supply device).

At block 708, process 700 can cause the word line driver to switch from being powered by the word line supply device to floating. For example, in instances in which a word line supply enable signal is an inverted signal (e.g., as shown in and described above in connection with FIG. 5), process 700 can cause the word line supply enable signal to switch from a low state (in which the word line driver is connected to the word line supply) to a high state (in which the word line driver is not connected to the word line supply, and is therefore, in a floating state).

At block 710, process 700 can cause voltage boosting drivers to turn on. For example, process 700 can set one or more boost switches (e.g., as shown in and described above in connection with FIG. 5), each associated with a boost driver, to switch to a high state. Continuing with this example, when a boost switch is set to a high state, an output of a boost driver (i.e., a boost buffer) may be correspondingly high. Accordingly, when a boost switch is set high, the charge stored in the driver or buffer may be transferred to the word line driver via one or more boost capacitors that capacitively couple the word line driver to the boost driver. Accordingly, the voltage provided to the word line driver may be boosted (i.e., to VBST) by the charge transferred from the buffer.

At block 712, process 700 can perform the write operation at the bit cell corresponding to the local column selected at block 706.

At block 714, process 700 can cause the word line driver to switch back to being powered by the word line supply device. For example, in some embodiments, process 700 can switch a word line supply enable signal. As a more particular example, in instances in which the word line supply enable signal is an inverted signal, process 700 can switch the word line supply enable signal from a high state to a low state.

At block 716, process 700 causes the voltage boosting drivers to be turned off. For example, in some embodiments, process 700 can switch the boost switches to an off state or to a low state, thereby causing the output of the boost drivers to be correspondingly low. It should be noted that, after execution of blocks 714 and 716, the word line driver voltage drops from VBST to VDDA.

At block 718, process 700 disables the selection of the local column corresponding to the write operation that was performed at block 712. At block 720, process 700 determines whether all local columns in the set of columns have been selected. If, at block 720, process 700 determines that not all local columns have been selected (“no” at block 720), process 700 can loop back to block 706 and can select the next local column in the set of columns corresponding to the sequence of write operations. Process 700 can loop through blocks 704-720 until write operations have been performed at bit cells associated with all of the local columns of the set of columns. It should be noted, during loops through blocks 704-720 after the initial loop, the word line is not asserted at block 706, because the word line remains asserted each of the loops through blocks 704-720.

Conversely, if, at block 720, process 700 determines that all local columns have been selected (“yes” at 720), process 700 can proceed to block 722 and can de-assert the word line.

In some embodiments, a boost capacitor may be implemented as a metal-insulator-metal capacitor (MIMCAP). Additionally or alternatively, in some embodiments, a boost capacitor may be implemented as a metal-oxide-silicon capacitor (MOSCAP). The MOSCAP may include a PMOS field effect transistor (FET) or an NMOS FET. In instances in which the MOSCAP is a p-type MOSCAP, the connected drain, source, and body may act as an anode terminal, and the gate may act as the cathode terminal. Conversely, in instances in which the MOSCAP is an n-type MOSCAP, the connected drain, source, and body may act as a cathode terminal, and the gate may act as the anode terminal.

FIG. 8A shows a schematic diagram of an example MOSCAP 800 that may be used to implement a boost capacitor. As illustrated, MOSCAP 800 includes a substrate 802, source/drain contacts 804, 806, and 808, and gate terminals 810 and 812. Source/drain contacts 804 and 806 and gate terminal 810 effectively form a first transistor in parallel with a second transistor formed by source/drain contacts 806 and 808 and gate terminal 812. Because the overall capacitance of MOSCAP 800 may depend on the total gate area (e.g., of gate terminal 810 and gate terminal 812), the overall capacitance of MOSCAP 800 may be increased relative to only using a single gate terminal.

FIG. 8B illustrates use of various types of MOSCAPs in accordance with some embodiments. For example, MOSCAP 852 and MOSCAP 854 are n-type MOSCAPs. As another example, MOSCAP 856 and MOSCAP 858 are p-type MOSCAPs. As illustrated with MOSCAPs 852 and 856), the gate is connected to the boost switch. Conversely, for MOSCAPs 854 and 858), the source/drain is connected to the boost switch. It should be noted that, in some instances in which the word line supply voltage is higher than an output of a boost driver, MOS CAP 854 and/or MOSCAP 856 may be preferable because capacitance density will be higher when the gate of an n-type MOSCAP is used as anode (MOSCAP 854) or the gate of a p-type MOSCAP is used as cathode (MOSCAP 856). In such instances, where MOSCAP 852 and/or MOSCAP 858 are used, the effective capacitance may be lower.

In some implementations, voltage boosting may be performed by boosting the word line signal itself rather than boosting a supply of a word line driver that drives the word line. For example, in some embodiments, a boost capacitor may be implemented as a parallel route to the word line, where the parallel route transfers charge to the word line via parasitic coupling between the parallel route and the word line. As a more particular example, a boost capacitor may be implemented as a trace on a layer of an integrated circuit on which the SRAM device is fabricated such that there is capacitive coupling between the trace(s) and the word line. The parallel routes may be on the M1 layer of the integrated circuit, the M3 layer of the integrated circuit, or the like. In some embodiments, the word line is connected to a word line driver that causes the word line to be driven by the word line driver, and therefore, to have a voltage associated with the word line driver supply device (i.e., VDDA). In some embodiments, the word line driver has a tri-state design in which the word line driver is then switched to a high impedance state such that the word line is floating after being driven to the VDDA voltage. By switching the word line driver to the high impedance state, charge from traces parallel to the word line (i.e., one or more boost capacitors, each corresponding to a trace parallel to the word line) are used to boost the word line voltage by transferring charge to the word line via the capacitive coupling.

In some embodiments, a word line is associated with two parallel routes, each functioning as a boost capacitor, where each parallel route is capacitively coupled to the word line, and therefore, may boost the voltage of the word line. In some implementations, each parallel route may be independently controlled by a boost switch that is connected to a boost driver (i.e., boost buffer) that pushes charge to the parallel route. For example, the boost driver or boost buffer may have a high output responsive to the boost switch having a high value. In some embodiments, the amount of voltage boost provided to the word line may be configurable and/or controllable via the boost switches associated with each parallel route. For example, in some embodiments, a larger voltage boost may be achieved by setting both boost switches to have a high value relative to an instance in which only one boost switch of the two boost switches are set to a high value.

FIG. 9A shows an example schematic diagram for boosting a word line signal using parallel routes to the word line as boost capacitors in accordance with some embodiments. As illustrated, a word line 902 is associated with two parallel routes, 904 and 906, each functioning as a boost capacitor. Note that word line 902 is denoted as “WL[n]” in FIG. 9, indicating that word line 902 is the n^{th} word line of a set of word lines of an SRAM device. The two parallel routes 904 and 906 are denoted as CBST[n−1] and CBST[n], respectively, because parallel route 904 (i.e., CBST[n−1]) is also associated with word line [n−1] (not shown). Similarly, parallel route 906 (i.e., CBST[n]) is also associated with word line [n+1] (not shown).

Each parallel route is connected to a boost driver (i.e., boost buffer). For example, parallel route 904 is connected to boost driver 912, and parallel route 906 is connected to boost driver 910. Each boost driver or boost buffer is controlled by a corresponding boost switch such that, when the boost switch has a high value, the output of the boost driver or buffer is correspondingly high. For example, boost driver 912 is controlled by boost switch 913, and boost driver 910 is controlled by boost switch 911.

FIG. 9A also illustrates an end stage of a word line driver 914. As described above, word line driver has a tri-state design. When enable signal 916 has a low value, word line driver causes word line 902 to be driven to a voltage associated with the word line supply device (i.e., to VDDA). After driving word line 902 to the word line supply device voltage, enable signal 916 is switched to a high value, thereby causing word line 902 to be floating. Because switching enable signal 916 to a high value causes word line driver 914 to be in a high impedance mode, charge transferred from parallel routes 904 and 906 boosts the voltage of the word line rather than being discharged through word line driver 914.

FIG. 9B illustrates a schematic diagram of use of parallel routes to boost word line voltage in accordance with some embodiments. As illustrated, each word line may have its voltage boosted by two parallel routes, each functioning as a boost capacitor. For example, word line 954 may have its voltage boosted by parallel routes 952 and 956. Similarly, word line 958 may have its voltage boosted by parallel routes 956 and 960. It should be noted that each parallel route may function as a boost capacitor for two word lines. In some embodiments, the parallel routes may be on an M1 layer of an integrated circuit on which the SRAM device is fabricated, on an M3 layer of the integrated circuit, or the like.

As described above in connection with FIG. 5, in instances in which the word line voltage is boosted by boosting the voltage of a word line driver that powers the word line, an amount of boosting voltage may be configurable by selecting boost capacitors out of a set of available boost capacitors. In particular, in some implementations, the amount of voltage boost (i.e., Δ=VBST−VDDA) is proportional to the total capacitance of the boost capacitors that are used. In one example, the amount of voltage boost is the ratio of the total capacitance of the boost capacitors to the capacitance connected to the word line driver node. In other words,

$$Δ = \frac{{CBST}_{total}}{{C}_{WL \_ total}} * VDDA ,$$

where CBSTₜₒₜₐₗ corresponds to the total capacitance of the boost capacitors that are used and C_{WL_total} corresponds to the capacitance connected to supply of the word line driver. By selecting which boost capacitors are used (via the corresponding boost switches), and therefore, controlling CBSTₜₒₜₐₗ, the amount of voltage boost can be controlled during operation of the SRAM device.

FIG. 10 shows a schematic diagram that illustrates a relationship between boost capacitors to boost voltage in accordance with some embodiments. In an instance in which the set of available boost capacitors is represented as a multiple of a unit boost capacitor (N*CBST), and in which k unit boost capacitors out of the set of N unit boost capacitors are used, the total capacitance of the used boost capacitors is k*CBST, where each boost capacitor may have different multiples of unit capacitance (CBST). The total capacitance connected to the word line corresponds to the used boost capacitors 1002 and the unused boost capacitors 1004 of the set of boost capacitors, the parasitic capacitance 1006 of the word line supply device and the supply voltage node of the word line driver, and the capacitance 1008 associated with the word line itself, all in parallel. Parasitic capacitance 1006 and word line capacitance 1008 are denoted as Cₓ in FIG. 10A. Accordingly, the amount of voltage boost is:

$$Δ = \frac{k * CBST}{N * CBST + {C}_{x}} * VDDA .$$

It should be noted that boost capacitors that are selected from a set of available boost capacitors may be identified based at least in part on PVT conditions. For example, a larger voltage boost may be used during sensitive conditions (e.g., low voltage conditions, low temperature conditions, or the like), and correspondingly, more boost capacitors, or relatively larger boost capacitors, may be used. As another example, a smaller voltage boost may be used during less sensitive conditions (e.g., higher voltage conditions, higher temperature conditions, or the like), and, correspondingly, fewer boost capacitors, or relatively smaller boost capacitors, may be used. Boost capacitors out of a set of available boost capacitors that are to be used for a given set of PVT conditions may be identified using a look up table. For example, particular PVT condition values may be used as keys to the look up table to identify whether particular boost capacitors are to be switched on. The values identified using the look up table may then be used as the boost switch signals shown in and described above (e.g., in connection with FIG. 7) to control the amount of voltage boost accordingly. In some embodiments, the look up table may be configured during testing of the SRAM device (e.g., factory testing) and used during operation of the SRAM device. For example, a controller associated with a SOC on which the SRAM device is included may access the look up table based on current operating conditions to identify or select boost capacitors out of a set of available boost capacitors to be used to provide a tailored amount of voltage boost suitable for the current operating conditions.

In some embodiments, in instances in which multiple boost capacitors out of a set of available boost capacitors are used, the multiple boost capacitors may be activated or switched on at slightly different times by staggering or dithering the timing of the corresponding boost switch signals. For example, timing of a first boost switch signal associated with a first boost buffer and/or first capacitor may be different than that of a second boost switch signal associated with a second boost buffer and/or second capacitor. Such dithering may serve to decrease the peak current of the word line and/or the bit cell array, thereby reducing supply noise and electro-migration reliability.

The integrated circuits described herein may be used in conjunction with various technologies, such as an artificial reality system. An artificial reality system, such as a head-mounted display (HMD) or heads-up display (HUD) system, generally includes a display configured to present artificial images that depict objects in a virtual environment. The display may present virtual objects or combine images of real objects with virtual objects, as in virtual reality (VR), augmented reality (AR), or mixed reality (MR) applications. For example, in an AR system, a user may view both displayed images of virtual objects (e.g., computer-generated images (CGIs)) and the surrounding environment by, for example, seeing through transparent display glasses or lenses (often referred to as optical see-through) or viewing displayed images of the surrounding environment captured by a camera (often referred to as video see-through). In some AR systems, the artificial images may be presented to users using an LED-based display subsystem.

In some embodiments, the integrated circuits or integrated circuit packages described herein may be integrated into an HMD. For example, such an HMD may include one or more light emitters and/or one or more light sensors incorporated into a portion of a frame of the HMD such that light can be emitted toward a tissue of a wearer of the HMD that is proximate to or touching the portion of the frame of the HMD. Example locations of such a portion of a frame of an HMD may include a portion configured to be proximate to an ear of the wearer (e.g., proximate to a superior tragus, proximate to a superior auricular, proximate to a posterior auricular, proximate to an inferior auricular, or the like), proximate to a forehead of the wearer, or the like. It should be noted that multiple sets of light emitters and light sensors may be incorporated into a frame of an HMD such that PPG can be determined from measurements associated with multiple body locations of a wearer of the HMD.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

Embodiments disclosed herein may be used to implement components of an artificial reality system or may be implemented in conjunction with an artificial reality system. Artificial reality is a form of reality that has been adjusted in some manner before presentation to a user, which may include, for example, a virtual reality, an augmented reality, a mixed reality, a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including an HMD connected to a host computer system, a standalone HMD, a mobile device or computing system, or any other hardware platform capable of providing artificial reality content to one or more viewers.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

### Example Embodiments

Embodiment 1: A system, comprising: a static random access memory (SRAM) device comprising: a bit cell array comprising a plurality of bit cells, the plurality of bit cells arranged in a plurality of rows and a plurality of columns, each column of the plurality of columns operatively coupled to a pair of bit lines; and a controller configured to: assert a word line associated with a row of the plurality of rows, perform a sequence of write operations while the word line remains asserted, each write operation of the sequence of write operations corresponding to a bit cell associated with a different column of the plurality of columns and the row, wherein the word line has an elevated voltage relative to a non-elevated voltage during at least a portion of the sequence of write operations, and de-assert the word line after the sequence of write operations are performed.

Embodiment 2: The system of embodiment 1, wherein the non-elevated voltage corresponds to a supply voltage associated with addressing circuitry of the SRAM device.

Embodiment 3: The system of embodiment 1, wherein the non-elevated voltage is associated with a supply voltage of a word line driver of the word line, and wherein the non-elevated voltage is used to assert the word line.

Embodiment 4: The system of any one of embodiments 1-3, wherein to perform the sequence of write operations, the controller is configured to cause the word line to have the elevated voltage for an entire duration of each of the sequence of write operations.

Embodiment 5: The system of any one of embodiments 1-3, wherein to perform the sequence of write operations, the controller is configured to cause the word line to have the supply voltage during a first portion of each write operation of the sequence of write operations, and to have the elevated voltage during a second portion of each write operation of the sequence of write operations.

Embodiment 6: The system of any one of embodiments 1-5, wherein the elevated voltage is determined based at least in part on conditions comprising process variations, voltage conditions, or temperature conditions.

Embodiment 7: The system of any one of embodiments 1-6, wherein the controller is configured to cause the word line to have the non-elevated voltage or the elevated voltage by controlling a voltage of a word line driver that is operatively coupled to the word line.

Embodiment 8: The system of embodiment 7, wherein the controller is configured to cause the word line to have the non-elevated voltage by causing the word line driver to be powered by a word line supply, and wherein the controller is configured to cause the word line to have the elevated voltage by causing the word line driver to be floating and capacitively coupled to one or more boost buffers.

Embodiment 9: The system of embodiment 8, wherein the capacitive coupling comprises one or more boost capacitors, the one or more boost capacitors comprising one or more metal-oxide-silicon capacitors (MOSCAPs) or one or more metal-insulator-metal capacitors (MIMCAPs).

Embodiment 10: The system of any one of embodiment 8, wherein the controller is configured to select boost capacitors of a set of available boost capacitors to be used to capacitively couple the word line driver to the one or more boost buffers during operation of the SRAM device, and wherein a magnitude of the second voltage is dependent on a number of boost capacitors selected.

Embodiment 11: The system of embodiment 10, wherein the boost capacitors of the set of available boost capacitors are selected based at least in part on conditions comprising process variations, voltage conditions, or temperature conditions.

Embodiment 12: The system of any one of embodiments 10 or 11, wherein the boost capacitors of the set of available boost capacitors are selected by accessing a look up table during operation of the SRAM device.

Embodiment 13: The system of any one of embodiments 9-12, wherein the one or more boost capacitors comprises at least two boost capacitors, each controlled by a switching signal, and wherein a timing of a first switching signal associated with a first boost capacitor differs from a timing of a second switching signal associated with a second boost capacitor.

Embodiment 14: The system of embodiment 1, wherein the controller is configured to cause the word line to have the word line voltage or the elevated voltage by controlling a voltage of the word line while causing a word line driver operatively coupled to the word line to have the word line voltage.

Embodiment 15: The system of embodiment 14, wherein the controller is configured to cause the word line to have the elevated voltage by transferring charge from one or more boost buffers to the word line, wherein the one or more boost buffers are capacitively coupled to the word line by one or more boost capacitors, and wherein the one or more boost capacitors are implemented as metal routes parallel to the word line.

Embodiment 16: The system of embodiment 15, wherein to transfer charge from the one or more boost buffers to the word line, the controller is configured to cause the word line driver to be in a high impedance mode.

Embodiment 17: The system of any one of embodiments 15 or 16, wherein the metal routes and the word line are implemented in an M3 layer of an integrated circuit on which the SRAM device is fabricated.

Embodiment 18: A method, comprising: asserting a word line associated with a row of a plurality of rows of a static random access memory (SRAM) device, the SRAM device comprising a bit cell array comprising a plurality of bit cells, the plurality of bit cells arranged in a plurality of rows and a plurality of columns, each column of the plurality of columns operatively coupled to a pair of bit lines; performing a sequence of write operations while the word line remains asserted, each write operation of the sequence of write operations corresponding to a bit cell associated with a different column of the plurality of columns and the row, wherein the word line has an elevated voltage relative to a non-elevated voltage during at least a portion of the sequence of write operations; and de-asserting the word line after the sequence of write operations are performed.

Embodiment 19: The method of embodiment 18, wherein performing the sequence of write operations comprises causing the word line to have the elevated voltage for an entire duration of each of the sequence of write operations.

Embodiment 20: The method of embodiment 18, wherein performing the sequence of write operations comprises causing the word line to have the supply voltage during a first portion of each write operation of the sequence of write operations, and to have the elevated voltage during a second portion of each write operation of the sequence of write operations.

Embodiment 21: The method of any one of embodiments 18-20, further comprising causing the word line to have the non-elevated voltage or the elevated voltage by controlling a voltage of a word line driver that is operatively coupled to the word line.

Embodiment 22: The method of embodiment 21, wherein causing the word line to have the non-elevated voltage comprises causing the word line driver to be powered by a word line supply, and wherein causing the word line to have the elevated voltage comprises causing the word line driver to be floating and capacitively coupled to one or more boost buffers.

Embodiment 23: The method of any one of embodiments 18-20, further comprising causing the word line to have the word line voltage or the elevated voltage by controlling a voltage of the word line while causing a word line driver operatively coupled to the word line to have the word line voltage.

Embodiment 24: The method of embodiment 23, wherein causing the word line to have the elevated voltage comprises transferring charge from one or more boost buffers to the word line, wherein the one or more boost buffers are capacitively coupled to the word line by one or more boost capacitors, and wherein the one or more boost capacitors are implemented as metal routes parallel to the word line.

Embodiment 25: An apparatus, comprising: a static random access memory (SRAM) device comprising: a bit cell array comprising a plurality of bit cells, the plurality of bit cells arranged in a plurality of rows and a plurality of columns, each column of the plurality of columns operatively coupled to a pair of bit lines; means for asserting a word line associated with a row of the plurality of rows; means for performing a sequence of write operations while the word line remains asserted, each write operation of the sequence of write operations corresponding to a bit cell associated with a different column of the plurality of columns and the row, wherein the word line has an elevated voltage relative to a non-elevated voltage during at least a portion of the sequence of write operations; and means for de-asserting the word line after the sequence of write operations are performed.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments were described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof. When implemented in software, firmware, middleware, or microcode, the program code or code segments to perform the associated tasks may be stored in a computer-readable medium such as a storage medium. Processors may perform the associated tasks.

It will be apparent to those skilled in the art that substantial variations may be made in accordance with specific requirements. For example, customized or special-purpose hardware might also be used, and/or particular elements might be implemented in hardware, software (including portable software, such as applets, etc.), or both. Further, connection to other computing devices such as network input/output devices may be employed.

With reference to the appended figures, components that can include memory can include non-transitory machine-readable media. The term “machine-readable medium” and “computer-readable medium” may refer to any storage medium that participates in providing data that causes a machine to operate in a specific fashion. In embodiments provided hereinabove, various machine-readable media might be involved in providing instructions/code to processing units and/or other device(s) for execution. Additionally or alternatively, the machine-readable media might be used to store and/or carry such instructions/code. In many implementations, a computer-readable medium is a physical and/or tangible storage medium. Such a medium may take many forms, including, but not limited to, non-volatile media, volatile media, and transmission media. Common forms of computer-readable media include, for example, magnetic and/or optical media such as compact disk (CD) or digital versatile disk (DVD), punch cards, paper tape, any other physical medium with patterns of holes, a RAM, a programmable read-only memory (PROM), an erasable programmable read-only memory (EPROM), a FLASH-EPROM, any other memory chip or cartridge, a carrier wave as described hereinafter, or any other medium from which a computer can read instructions and/or code. A computer program product may include code and/or machine-executable instructions that may represent a procedure, a function, a subprogram, a program, a routine, an application (App), a subroutine, a module, a software package, a class, or any combination of instructions, data structures, or program statements.

Those of skill in the art will appreciate that information and signals used to communicate the messages described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, AB, AC, BC, AA, ABC, AAB, AABBCCC, etc.

Further, while certain embodiments have been described using a particular combination of hardware and software, it should be recognized that other combinations of hardware and software are also possible. Certain embodiments may be implemented only in hardware, or only in software, or using combinations thereof. In one example, software may be implemented with a computer program product containing computer program code or instructions executable by one or more processors for performing any or all of the steps, operations, or processes described in this disclosure, where the computer program may be stored on a non-transitory computer readable medium. The various processes described herein can be implemented on the same processor or different processors in any combination.

Where devices, systems, components or modules are described as being configured to perform certain operations or functions, such configuration can be accomplished, for example, by designing electronic circuits to perform the operation, by programming programmable electronic circuits (such as microprocessors) to perform the operation such as by executing computer instructions or code, or processors or cores programmed to execute code or instructions stored on a non-transitory memory medium, or any combination thereof. Processes can communicate using a variety of techniques, including, but not limited to, conventional techniques for inter-process communications, and different pairs of processes may use different techniques, or the same pair of processes may use different techniques at different times.

The specification and drawings are, accordingly, to be regarded in an illustrative rather than a restrictive sense. It will, however, be evident that additions, subtractions, deletions, and other modifications and changes may be made thereunto without departing from the broader spirit and scope as set forth in the claims. Thus, although specific embodiments have been described, these are not intended to be limiting. Various modifications and equivalents are within the scope of the following claims.

What is claimed is:

1. A system, comprising:
a static random access memory (SRAM) device comprising:
a bit cell array comprising a plurality of bit cells, the plurality of bit cells arranged in a plurality of rows and a plurality of columns, each column of the plurality of columns operatively coupled to a pair of bit lines;
a controller configured to:
assert a word line associated with a row of the plurality of rows,
perform a sequence of write operations while the word line remains asserted, each write operation of the sequence of write operations corresponding to a bit cell associated with a different column of the plurality of columns and the row, wherein the word line has an elevated voltage relative to a non-elevated voltage during at least a portion of the sequence of write operations, and
de-assert the word line after the sequence of write operations are performed.

2. The system of claim 1, wherein the non-elevated voltage corresponds to a supply voltage associated with addressing circuitry of the SRAM device.

3. The system of claim 1, wherein the non-elevated voltage is associated with a supply voltage of a word line driver of the word line, and wherein the non-elevated voltage is used to assert the word line.

4. The system of claim 1, wherein to perform the sequence of write operations, the controller is configured to cause the word line to have the elevated voltage for an entire duration of each of the sequence of write operations.

5. The system of claim 1, wherein to perform the sequence of write operations, the controller is configured to cause the word line to have the supply voltage during a first portion of each write operation of the sequence of write operations, and to have the elevated voltage during a second portion of each write operation of the sequence of write operations.

6. The system of claim 1, wherein the elevated voltage is determined based at least in part on conditions comprising process variations, voltage conditions, or temperature conditions.

7. The system of claim 1, wherein the controller is configured to cause the word line to have the non-elevated voltage or the elevated voltage by controlling a voltage of a word line driver that is operatively coupled to the word line.

8. The system of claim 7, wherein the controller is configured to cause the word line to have the non-elevated voltage by causing the word line driver to be powered by a word line supply, and wherein the controller is configured to cause the word line to have the elevated voltage by causing the word line driver to be floating and capacitively coupled to one or more boost buffers.

9. The system of claim 8, wherein the capacitive coupling comprises one or more boost capacitors, the one or more boost capacitors comprising one or more metal-oxide-silicon capacitors (MOSCAPs) or one or more metal-insulator-metal capacitors (MIMCAPs).

10. The system of claim 8, wherein the controller is configured to select boost capacitors of a set of available boost capacitors to be used to capacitively couple the word line driver to the one or more boost buffers during operation of the SRAM device, and wherein a magnitude of the second voltage is dependent on a number of boost capacitors selected.

11. The system of claim 10, wherein the boost capacitors of the set of available boost capacitors are selected based at least in part on conditions comprising process variations, voltage conditions, or temperature conditions.

12. The system of claim 10, wherein the boost capacitors of the set of available boost capacitors are selected by accessing a look up table during operation of the SRAM device.

13. The system of claim 9, wherein the one or more boost capacitors comprises at least two boost capacitors, each controlled by a switching signal, and wherein a timing of a first switching signal associated with a first boost capacitor differs from a timing of a second switching signal associated with a second boost capacitor.

14. The system of claim 1, wherein the controller is configured to cause the word line to have the word line voltage or the elevated voltage by controlling a voltage of the word line while causing a word line driver operatively coupled to the word line to have the word line voltage.

15. The system of claim 14, wherein the controller is configured to cause the word line to have the elevated voltage by transferring charge from one or more boost buffers to the word line, wherein the one or more boost buffers are capacitively coupled to the word line by one or more boost capacitors, and wherein the one or more boost capacitors are implemented as metal routes parallel to the word line.

16. The system of claim 15, wherein to transfer charge from the one or more boost buffers to the word line, the controller is configured to cause the word line driver to be in a high impedance mode.

17. The system of claim 15, wherein the metal routes and the word line are implemented in an M3 layer of an integrated circuit on which the SRAM device is fabricated.

18. A method, comprising:
asserting a word line associated with a row of a plurality of rows of a static random access memory (SRAM) device, the SRAM device comprising a bit cell array comprising a plurality of bit cells, the plurality of bit cells arranged in a plurality of rows and a plurality of columns, each column of the plurality of columns operatively coupled to a pair of bit lines;
performing a sequence of write operations while the word line remains asserted, each write operation of the sequence of write operations corresponding to a bit cell associated with a different column of the plurality of columns and the row, wherein the word line has an elevated voltage relative to a non-elevated voltage during at least a portion of the sequence of write operations; and
de-asserting the word line after the sequence of write operations are performed.

19. The method of claim 18, wherein performing the sequence of write operations comprises causing the word line to have the elevated voltage for an entire duration of each of the sequence of write operations.

20. An apparatus, comprising:
a static random access memory (SRAM) device comprising:
a bit cell array comprising a plurality of bit cells, the plurality of bit cells arranged in a plurality of rows and a plurality of columns, each column of the plurality of columns operatively coupled to a pair of bit lines;
means for asserting a word line associated with a row of the plurality of rows;
means for performing a sequence of write operations while the word line remains asserted, each write operation of the sequence of write operations corresponding to a bit cell associated with a different column of the plurality of columns and the row, wherein the word line has an elevated voltage relative to a non-elevated voltage during at least a portion of the sequence of write operations; and
means for de-asserting the word line after the sequence of write operations are performed.
